(19) United States
(12) Patent Application Publication
(10) Pub. No.: US 2021/0328192 A1
(43) Pub. Date: Oct. 21, 2021

(54) OLED DISPLAY PANEL, MANUFACTURING METHOD THEREOF, AND DISPLAY DEVICE

(71) Applicant: Wuhan China Star Optoelectronics Semiconductor Display Technology Co., Ltd., Wuhan, Hubei (CN)

(72) Inventor: Chen XIA, Wuhan, Hubei (CN)

(21) Appl. No.: 16/624,223

(22) PCT Filed: Nov. 4, 2019
(86) PCT No.: PCT/CN2019/115246

§ 371 Date: Dec. 18, 2019

(30) Foreign Application Priority Data
Jun. 18, 2019 (CN) 201910526068.6

(51) Int. Cl. H01L 51/52; H01L 51/56

(52) U.S. Cl. CPC H01L 51/5268; H01L 51/5253; H01L 27/3244; H01L 2251/5369; H01L 51/56

(57) ABSTRACT

An organic light-emitting diode (OLED) display panel, a manufacturing method thereof, and a display device are provided. The OLED display panel includes a first inorganic encapsulation layer, a buffer layer disposed on the first inorganic encapsulation layer, a metal particle film layer prepared on the buffer layer and converted to be a scattering layer under an energy modification of the buffer layer, and an organic encapsulation layer disposed on the scattering layer. Thus, a metal surface plasmon resonance effect is utilized to improve light generated by decay of excitons in the emissive layer and extraction of incident light from an absorbing active layer, thereby enhancing the external quantum efficiency.

### FIELD OF INVENTION

The present invention relates to a field of display technologies, and in particular, to an organic light emitting diode (OLED) display panel, a manufacturing method thereof, and a display device.

### BACKGROUND OF INVENTION

In recent years, organic light emitting diode (OLED) display technologies have developed by leaps and bounds. OLED products have attracted more and more attention and had more and more applications due to their advantages of thinness, lightness, fast response times, wide viewing angles, high contrast, and flexibility, which are mainly used in display fields, such as mobile phones, tablets, and televisions.

As shown in FIG. 1, an OLED display device specifically includes an OLED display panel which is including a base layer 110, a thin film field effect transistor (TFT) driving layer 120, an OLED luminescent layer 130, a first inorganic encapsulation layer 140, an organic encapsulation layer 150, a second inorganic encapsulation layer 160, and the like from bottom to top. The principle of OLED luminescence is to deposit the OLED luminescent layer 130 between two electrodes, then apply a current to the OLED luminescent layer 130, and cause the OLED luminescent layer 130 to emit light by carriers injection and recombination.

Technical problem: currently, with the development of phosphorescent and thermally activated delayed fluorescent materials in the OLED luminescent layer 130, an internal quantum efficiency may theoretically reach 100%, but an external quantum efficiency of the OLED luminescent layer 130 is still limited by waveguides, substrates, surface plasmon resonance, and the like, so that the external quantum efficiency is largely lost. Among them, reflected light loss is a main influence. Therefore, how to improve the external quantum efficiency has become key research projects of relevant developers.

### SUMMARY OF INVENTION

An object of the present invention is to provide an organic light-emitting diode (OLED) display panel, a manufacturing method thereof, and a display device. The OLED display panel includes a first inorganic encapsulation layer, a buffer layer disposed on the first inorganic encapsulation layer, a metal particle film layer prepared on the buffer layer and converted to be a scattering layer under an energy modification of the buffer layer, and an organic encapsulation layer disposed on the scattering layer. Thus, a metal surface plasmon resonance effect is utilized to improve light generated by decay of excitons in the emissive layer and extraction of incident light from an absorbing active layer, thereby enhancing the external quantum efficiency.

According to an aspect of the present invention, the present invention provides an organic light-emitting diode (OLED) display panel, including: a substrate; a thin film transistor layer and an organic luminescent layer sequentially disposed on the substrate; and a first inorganic encapsulation layer disposed on the organic luminescent layer, the OLED display panel further including: a buffer layer disposed on the first inorganic encapsulation layer; and a scattering layer disposed on the buffer layer, wherein the scattering layer includes a plurality of metal particles configured to reduce an absorptivity of light and enhance a scattering efficiency; the OLED display panel further including: a first organic encapsulation layer disposed on the scattering layer; and a second inorganic encapsulation layer disposed on the first organic encapsulation layer; wherein the metal particles are formed of silver ions, and a particle diameter of the metal particles ranges from 50 nanometers to 150 nanometers.

According to another aspect of the present invention, the present invention provides an organic light-emitting diode (OLED) display panel, including: a substrate; a thin film transistor layer and an organic luminescent layer sequentially disposed on the substrate; and a first inorganic encapsulation layer disposed on the organic luminescent layer, the OLED display panel further including: a buffer layer disposed on the first inorganic encapsulation layer; and a scattering layer disposed on the buffer layer, wherein the scattering layer includes a plurality of metal particles configured to reduce an absorptivity of light and enhance a scattering efficiency.

In an embodiment of the present invention, the OLED display panel further includes a first organic encapsulation layer disposed on the scattering layer.

In an embodiment of the present invention, the OLED display panel further includes a second inorganic encapsulation layer disposed on the first organic encapsulation layer.

In an embodiment of the present invention, the metal particles are formed of silver ions.

In an embodiment of the present invention, a particle diameter of the metal particles is nanoscale, preferably, a particle diameter of the metal particles ranges from 50 nanometers to 150 nanometers.

In an embodiment of the present invention, the buffer layer is made of poly(ethylenedioxythiophene)-poly(styrenesulfonate), and a thickness of the buffer layer ranges from 1 to 1.5 μm.

In an embodiment of the present invention, material of the first organic encapsulation layer is polymethyl methacrylate, and a thickness of the first organic encapsulation layer ranges from 3 to 8 μm.

In an embodiment of the present invention, material of the second inorganic encapsulation layer and material of the first inorganic encapsulation layer are silicon nitride or silicon oxide, and each of a thickness of the second inorganic encapsulation layer and a thickness of the first inorganic encapsulation layer ranges from 0.5 to 1 μm.

According to yet another aspect of the present invention, the present invention provides a manufacturing method of above-described organic light-emitting diode (OLED) display panel, including steps of: providing a substrate, a thin film transistor layer, an organic luminescent layer, and a first inorganic encapsulation layer sequentially formed on the substrate; preparing a buffer layer on the first inorganic encapsulation layer by coating; preparing a metal particle film layer on the buffer layer by evaporation; increasing a particle diameter of metal particles in the metal particle film layer under an energy modification of the buffer layer by a low temperature annealing treatment, so that the metal particle film layer is converted to be a scattering layer: preparing a first organic encapsulation layer on the scattering layer by inkjet printing; and forming a second inorganic encapsulation layer on the first organic encapsulation layer by chemical vapor deposition.

According to still another aspect of the present invention, the present invention provides a display device including the above-described OLED display panel.

Beneficial effect: an advantage of the present invention is that an OLED display panel of the present invention is provided with a buffer layer on a first inorganic encapsulation layer, and a metal particle film layer is prepared on the buffer layer and converted to be a scattering layer under an energy modification of the buffer layer, and an organic encapsulation layer disposed on the scattering layer. Thus, a metal surface plasmon resonance effect is utilized to improve light generated by decay of excitons in the emissive layer and extraction of incident light from an absorbing active layer, thereby enhancing the external quantum efficiency.

### DRAWINGS

In order to more clearly illustrate the technical solutions in the embodiments of the present invention, the drawings used in the description of the embodiments will be briefly described below. It is apparent that the drawings in the following description are only some embodiments of the present invention. Other drawings can also be obtained from those skilled in the art based on these drawings without paying any creative effort.

FIG. 1 is a schematic structural view of an organic light emitting diode (OLED) display panel according to prior art.

FIG. 2 is a schematic structural view of an OLED display panel in an embodiment according to the present invention.

FIG. 3 is a flowchart showing a manufacturing method of the OLED display panel in the embodiment according to the present invention.

FIGS. 4A to 4F are process flowcharts of the manufacturing method of the OLED display panel in the embodiment according to the present invention.

FIG. 5 is a schematic structural view of a display device in an embodiment according to the present invention.

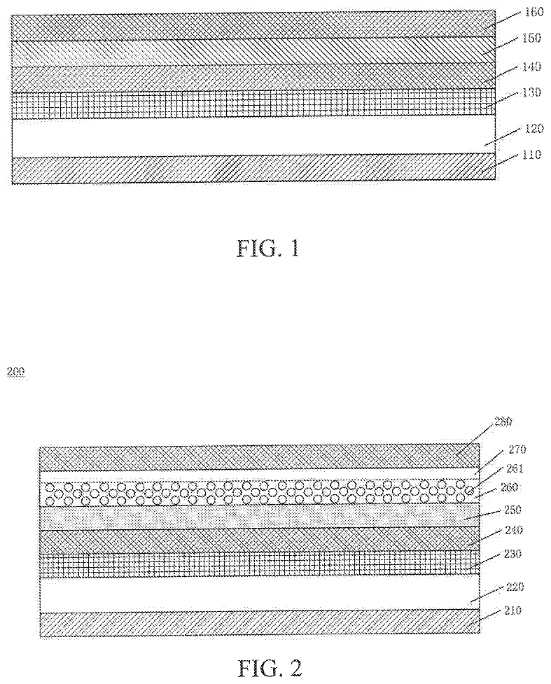

### DETAILED DESCRIPTION OF EMBODIMENTS

The technical solutions in the embodiments of the present invention will be clearly and completely described in the following in conjugation with the accompanying drawings. It is apparent that the described embodiments are only a part of the embodiments of the invention, and not all of the embodiments. All other embodiments obtained by those skilled in the art based on the embodiments of the present invention without creative efforts are within the scope of the present invention.

The terms “first”, “second”, “third”, etc. (if present) in the specification and claims of the present invention and the above-described figures are used to distinguish similar objects and are not intended to use to describe a particular order or prioritization. It should be understood that the objects described are interchangeable where appropriate. Moreover, the terms “comprising”, “including” and “having” and “the” and any variants thereof, are intended to cover non-exclusive inclusions.

In this patent document, the drawings, which are discussed below, and the various embodiments used to describe the principles of the present invention are intended to be illustrative only and not to limit the scope of the disclosure. Those skilled in the art will apparent that the principles of the present invention may be implemented in any suitably arranged system. Exemplary embodiments will be described in detail, examples of which are illustrated in the accompanying drawings. Further, a terminal according to an exemplary embodiment will be described in detail with reference to the accompanying drawings. The same reference numerals in the drawings denote the same elements.

The terms used in the description of the present invention are only used to describe specific embodiments, and not intended to illustrate the concept of the invention. Expressions used in the singular encompasses plural forms of expression unless the context clearly dictates otherwise. In the description of the present invention, it is to be understood that terms such as “comprises”, “comprising”, “having”, “includes”, “including” are intended to illustrate the possibilities of the features, numbers, steps, acts, or combinations thereof disclosed in the description of the invention, and not intended to exclude existence or addition of the possibility that one or more other features, numbers, steps, acts or combinations. The same reference numerals in the drawings denote the same parts.

Embodiments of the present invention provide an organic light emitting diode (OLED) display panel and a display device. The details will be described separately below,

Referring to FIG. 2, in an embodiment of the present invention, an OLED display panel 200 is provided. The OLED display panel 200 includes a substrate 210, a thin film transistor layer 220 and an organic luminescent layer 230, which are sequentially disposed on the substrate 210, and a first inorganic encapsulation layer 240 disposed on the organic luminescent layer 230.

The substrate 210 may be a polyimide (PI) substrate, a glass substrate, or a plastic substrate. A specific structure of the thin film transistor layer 220 is well known to those skilled in the art and will not be described in detail herein.

Material of the first inorganic encapsulation layer 240 is silicon nitride or silicon oxide, and a thickness of the first inorganic encapsulation layer 240 ranges from 0.5 to 1 μm.

The OLED display panel 200 further includes: a buffer layer 250 disposed on the first inorganic encapsulation layer 240; and a scattering layer 260 disposed on the buffer layer 250. The scattering layer includes a plurality of metal particles configured to reduce an absorptivity of light and enhance a scattering efficiency.

Specifically, material of the buffer layer 250 is made of poly-(ethylene-dioxy-thiophene)-poly(styrenesulfonate) (PEDOT:PSS), and a thickness of the buffer layer 250 ranges from 1 to 1.5 μm.

The scattering layer 260 is disposed on the buffer layer 250, and the scattering layer 260 includes a plurality of metal particles 261, the metal particles 261 may be formed of silver ions, certainly not only limited to silver ions, but also other metal ions. A particle diameter of the metal particles 261 is in nanoscale, for example, 100 nanometers or less. When the metal particles 261 are subjected to a surface energy modification of the buffer layer 250, and via an annealing treatment, the particle diameter of the metal particles 261 is increased. Therefore, the particle diameter of the metal particles ranges from 50 nanometers to 150 nanometers. Thus, in the present invention, a metal surface plasmon resonance effect is utilized to improve light generated by decay of excitons in an emissive layer and extraction of incident light from an absorbing active layer, thereby enhancing the external quantum efficiency. The emissive layer and the active layer are disposed in an OLED encapsulation structure, and the emissive layer is a transport film layer between the OLED cathode and the air, thereby improving light efficiency by reducing light loss in the transport film layer. The active layer is a film layer distributed over a light transmission path, and the film layer includes the above-described metal particles (nanoscale silver ions), which can improve extraction of incident light.

Continuing to refer to FIG. 2, the OLED display panel 200 further includes a first organic encapsulation layer 270 disposed on the scattering layer 260. Material of the first organic encapsulation layer 270 is polymethylmethacrylate (PMMA), and a thickness of the first organic encapsulation layer 270 ranges from 3 μm to 8 μm, The first organic encapsulation layer 270 is used for planarization of the scattering layer 260, and can also prolong moisture and oxygen permeation path and delay the aging of the device.

The OLED display panel 200 further includes a second inorganic encapsulation layer 280 disposed on the first organic encapsulation layer 270. Material of the second inorganic encapsulation layer 280 is silicon nitride or silicon oxide, and a thickness of the second inorganic encapsulation layer 280 ranges from 0.5 μm to 1 μm.

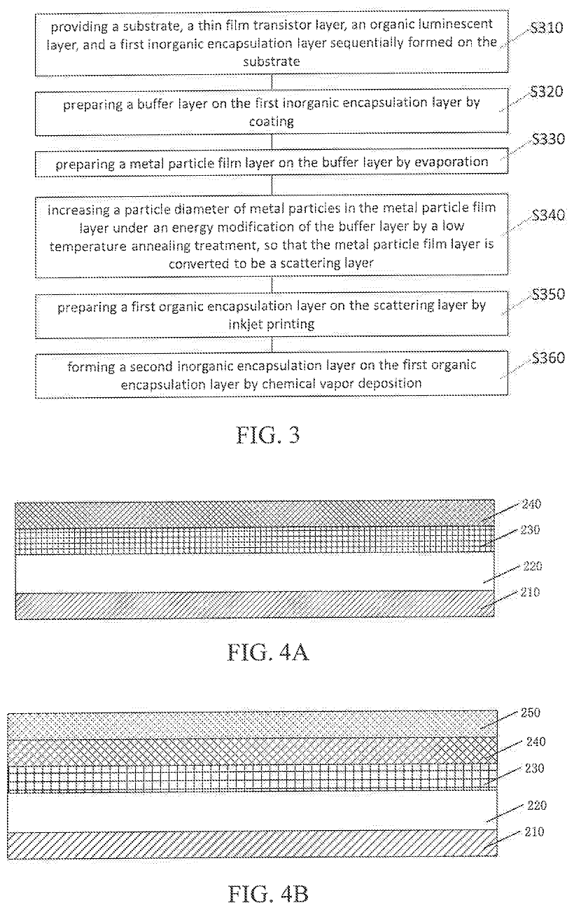

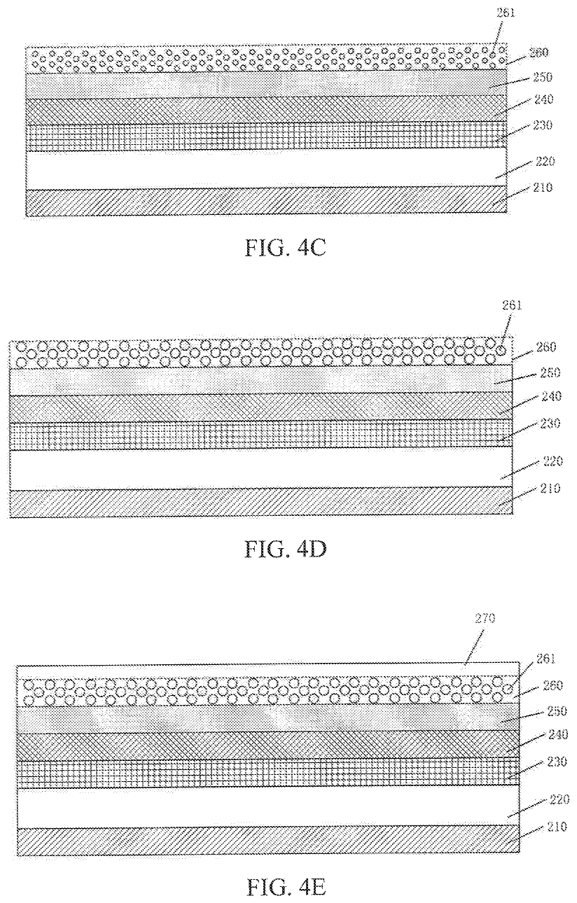

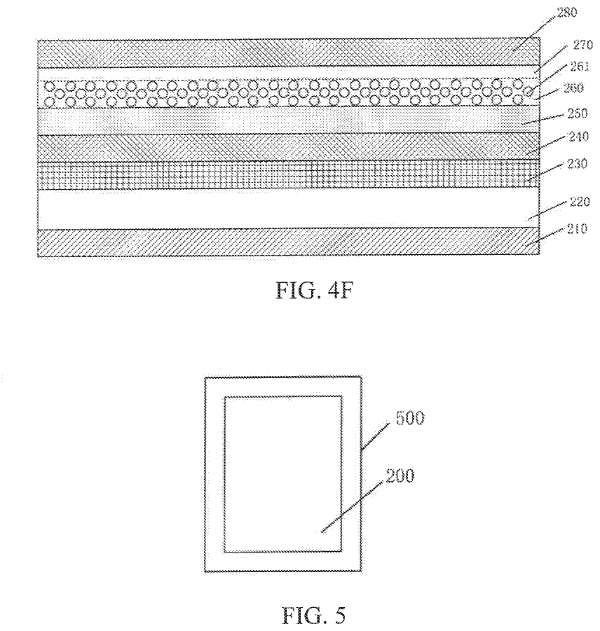

FIG. 3 is a flowchart of a manufacturing method of the above-described OLED display panel 200 in the embodiment according to the present invention. FIGS. 4A to 4F are process flowcharts of a manufacturing method of the OLED display panel 200 in the embodiment according to the present invention.

As shown in FIG. 3, the present invention provides a manufacturing method of the above-described OLED display panel 200. The method includes:

As shown in FIG. 4A, step S310: providing a substrate, a thin film transistor layer, an organic luminescent layer, and a first inorganic encapsulation layer sequentially formed on the substrate.

The substrate 210 may be a polyimide (PI) substrate, a glass substrate, or a plastic substrate. A specific structure of the thin film transistor layer 220 is well known to those skilled in the art and is not be described in detail herein.

The first inorganic encapsulation layer 240 is formed on the organic luminescent layer 230 by chemical vapor deposition. Material of the first inorganic encapsulation layer 240 is silicon nitride or silicon oxide, and a thickness of the first inorganic encapsulation layer 240 ranges from 0.5 μm to 1 μm.

Referring to FIG. 4B, step S320: preparing a buffer layer on the first inorganic encapsulation layer by coating.

Material of the buffer layer 250 is poly-(ethylenedioxythiophene)-poly(styrenesulfonate) (PEDOT:PSS), and a thickness of the buffer layer 250 ranges from 1 to 1.5 μm.

Referring to FIG. 4C, step S330: preparing a metal particle film layer on the buffer layer by evaporation.

In this embodiment, the metal particles 261 are silver particles, and a particle diameter is nanoscale. A thickness of the metal particle film layer (its reference numeral is 260, which is the same as the scattering layer) ranges from 10 to 12 nm.

As shown in FIG. 4D, step S340: increasing a particle diameter of metal particles in the metal particle film layer under an energy modification of the buffer layer by a low temperature annealing treatment, so that the metal particle film layer is converted to be a scattering layer.

When the silver particles are subjected to a surface energy modification of the buffer layer 250, the particle diameter of the particles is increased after annealing, and thus the particle diameter of the silver particles may exceed 100 nm, for example, 120 nm, 130 nm or even 150 nm. Therefore, in the present invention, the silver surface plasmon resonance effect is utilized to improve the extraction of light generated by decay of excitons in the emissive layer and extraction of incident light from an absorbing active layer, thereby enhancing the external quantum efficiency.

Referring to FIG. 4E, step S350: preparing a first organic encapsulation layer on the scattering layer by inkjet printing.

The first organic encapsulation layer 270 is disposed on the scattering layer 260 by an inkjet printing (IJP) manner. Material of the first organic encapsulation layer 270 is polymethylmethacrylate (PMMA), and a thickness of the first organic encapsulation layer 270 ranges from 3 to 8 μm. The first organic encapsulation layer 270 is used for planarization of the scattering layer 260, and can also prolong moisture and oxygen permeation path and delay the aging of the device.

Referring to FIG. 4F, step S360: forming a second inorganic encapsulation layer on the first organic encapsulation layer by chemical vapor deposition.

The second inorganic encapsulation layer 280 is disposed on the first organic encapsulation layer. Material of the second inorganic encapsulation layer 280 is silicon nitride or silicon oxide, and a thickness of the second inorganic encapsulation layer 280 ranges from 0.5 to 1 μm.

Therefore, after the implementation of the step S310 to step S360, a novel OLED display panel 200 can be obtained.

Referring to FIG. 5, in accordance with still another aspect of the present invention, there is provided with a display device 500 including the above-described OLED display panel 200. The display device 500 is used for display devices such, as liquid crystal televisions, monitors, mobile phones, or tablet computers.

An advantage of the present invention is that the OLED display panel 200 according to the present invention is provided with a buffer layer 250 disposed on a first inorganic encapsulation layer 240, a metal particle film layer prepared on the buffer layer 250 and converted to be a scattering layer 260 under an energy modification of the buffer layer 250, and a first organic encapsulation layer 270 disposed on the scattering layer 260. Thus, a metal surface plasmon resonance effect is utilized to improve light generated by decay of excitons in the emissive layer and extraction of incident light from an absorbing active layer, thereby enhancing the external quantum efficiency.

The above description is only preferred embodiments of the present invention. It should be noted that a number of modifications and refinements may be made by those skilled in the art without departing from the principles of the invention, and such modifications and refinements are also considered to be within the scope of the invention.

### INDUSTRIAL APPLICABILITY

the subject matter of the present application can be manufactured and used in the industry with industrial applicability.

1. An organic light-emitting diode (OLED) display panel, comprising:
a substrate;
a thin film transistor layer and an organic luminescent layer sequentially disposed on the substrate; and
a first inorganic encapsulation layer disposed on the organic luminescent layer,
the OLED display panel further comprising:
a buffer layer disposed on the first inorganic encapsulation layer; and
a scattering layer disposed on the buffer layer, wherein the scattering layer comprises a plurality of metal particles configured to reduce an absorptivity of light and enhance a scattering efficiency;
the OLED display panel further comprising:
a first organic encapsulation layer disposed on the scattering layer; and
a second inorganic encapsulation layer disposed on the first organic encapsulation layer;
wherein the metal particles are formed of silver ions, and
a particle diameter of the metal particles ranges from 50 nanometers to 150 nanometers.

2. An organic light-emitting diode (OLED) display panel, comprising:
a substrate;
a thin film transistor layer and an organic luminescent layer sequentially disposed on the substrate; and
a first inorganic encapsulation layer disposed on the organic luminescent layer,
the OLED display panel further comprising:
a buffer layer disposed on the first inorganic encapsulation layer; and
a scattering layer disposed on the buffer layer,
wherein the scattering layer comprises a plurality of metal particles configured to reduce an absorptivity of light and enhance a scattering efficiency.

3. The OLED display panel according to claim 2, wherein the OLED display panel further comprises a first organic encapsulation layer disposed on the scattering layer.

4. The OLED display panel according to claim 3, wherein the OLED display panel further comprises a second inorganic encapsulation layer disposed on the first organic encapsulation layer.

5. The OLED display panel according to claim 2, wherein the metal particles are formed of silver ions.

6. The OLED display panel according to claim 2, wherein a particle diameter of the metal particles is nanoscale.

7. The OLED display panel according to claim 2, wherein a particle diameter of the metal particles ranges from 50 nanometers to 150 nanometers.

8. The OLED display panel according to claim 2, wherein the buffer layer is made of poly(ethylenedioxythiophene)-poly(styrenesulfonate), and a thickness of the buffer layer ranges from 1 to 1.5 μm.

9. The OLED display panel according to claim 3, wherein material of the first organic encapsulation layer is polymethyl methacrylate, and a thickness of the first organic encapsulation layer ranges from 3 to 8 μm.

10. The OLED display panel according to claim 4, wherein material of the second inorganic encapsulation layer and material of the first inorganic encapsulation layer are silicon nitride or silicon oxide, and each of a thickness of the second inorganic encapsulation layer and a thickness of the first inorganic encapsulation layer ranges from 0.5 to 1 μm.

11. A manufacturing method of an organic light-emitting diode (OLED) display panel according to claim 2, comprising steps of:
providing a substrate, a thin film transistor layer, an organic luminescent layer, and a first inorganic encapsulation layer sequentially formed on the substrate;
preparing a buffer layer on the first inorganic encapsulation layer by coating;
preparing a metal particle film layer on the buffer layer by evaporation;
increasing a particle diameter of metal particles in the metal particle film layer under an energy modification of the buffer layer by a low temperature annealing treatment, so that the metal particle film layer is converted to be a scattering layer;
preparing a first organic encapsulation layer on the scattering layer by inkjet printing; and
forming a second inorganic encapsulation layer on the first organic encapsulation layer by chemical vapor deposition.
